(19) United States
(12) Patent Application Publication
(10) Pub. No.: US 2009/0056374 A1
(43) Pub. Date: Mar. 5, 2009

(54) Gemstone Facet Configuration

(76) Inventor: Steven L. Abate, Cary, NC (US)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 11/848,469

(22) Filed: Aug. 31, 2007

(51) Int. Cl. A44C 17/00; A44C 17/02; C30B 23/00; C30B 33/00

(52) U.S. Cl. 63/26; 117/2; 117/84; 63/32

(57) ABSTRACT

A gemstone can include a crown portion having a table facet, a plurality of trapezoidal facets, a plurality of irregular-hexagonal facets, a plurality of irregular-pentagonal facets, and a plurality of triangular crown-facets. The gemstone can also include a pavilion portion having a plurality of first kite facets, a plurality of irregular-quadrilateral facets, a plurality of second kite facets, and a plurality of triangular pavilion-facets.

### TECHNICAL FIELD

This invention relates to facet configurations for gemstones, and more particularly, to facet configurations for silicon carbide gemstones.

### BACKGROUND

Few chemical compounds can be formed into valuable gemstones as only some compounds possess the appropriate physical properties. Gemstones can be made from diamond, formed from single crystalline carbon, and corundum, such as sapphire and ruby, formed from single crystalline aluminum oxide. These materials possess relatively unusual physical properties, including high hardness, high refractive index, and translucent color. A gemstone's value is partially due to these unusual properties and the ability of the gemstone to reflect light.

Material hardness can be defined using the Mohs system, which includes a scale from 1 to 10. Diamond is generally considered the hardest at 10, sapphire at 9, topaz 8 down to the softest mineral, talc, which is 1. Because of its rarity, emerald is considered a precious stone even though its hardness is 7.5, while other gems, such as chrysoberyl, topaz and garnet, are usually classified as semi-precious stones because of their lower hardness. Hardness has practical value in that it defines the ability of a gemstone to resist scratching.

Refractive index is an important gemstone property because it defines the ability of a gemstone to refract light. When high-refractive materials are fashioned into finished gemstones, they sparkle and appear brilliant because light that enters the gemstone can be internally reflected back to an observer. The characteristic sparkle of a diamond is dependent upon its high refractive index and the gemstone's facet configuration.

Another important gemstone property is color. Gemstone color can be affected by a variety of factors, including impurity atoms incorporated into the crystal lattice. For example, a ruby is a sapphire crystal (aluminum oxide) that contains a small concentration of chromium impurity atoms. Other impurity ions can be added to synthetic gemstones to create a range of possible colors.

In addition to naturally formed precious gemstones, various synthetic compounds can also be formed into gemstones, including silicon carbide (SiC). See U.S. Pat. No. 5,882,786. SiC can be formed with physical properties suitable for gemstones, such as 8.50-9.25 Mohs hardness, depending on the polytype, or atomic arrangement of the crystal lattice. SiC can also have a high refractive index, such as 2.50-2.71, again depending on the polytype. These and other properties make SiC an ideal compound from which to form gemstones.

While SiC and other compounds can be used to form gemstones, a stone's value can be significantly affected by the ability of the gemstone to reflect light and “sparkle.” The shape of a stone, or facet configuration, can significantly affect the ability of a gemstone to reflect light. Facet configurations that reflect large amounts of light are highly desirable as stones that exhibit greater “brilliance” are generally considered more valuable.

While facet configurations of diamonds, sapphires, and other precious gemstones are well known, such configurations are highly dependent upon the physical properties of the gemstone material. For example, a facet configuration suitable for a diamond may not be suitable for a sapphire due to different material properties of the two stones, such as refractive index. Existing facet configurations for diamonds and other compounds are generally not suitable for SiC gemstones due to different material properties. Diamond facet configurations may be unsuitable for use with SiC due to the different refractive indices, or other physical property differences between carbon and SiC. There exists a need for facet configurations designed to provide SiC gemstones with the ability to reflect large amounts of light to create a “brilliant sparkle” effect.

Not only are traditional facet configurations not suitable for SiC-based gemstones due to different material properties, but traditional configurations also suffer another constraint. Traditional facet configurations generally aim to preserve as much gemstone material as possible, as a gemstone's value is highly weight dependent. Larger stones are generally worth considerably more than similar smaller stones. Therefore, an important feature of traditional facet formation is the requirement that the amount of gemstone material removed to create the facet be minimized. Traditional gemstone shapes aim to preserve material during the faceting process in order to create a finished gemstone with the highest possible weight. As such, traditional facet configurations are designed to remove as little material as possible while retaining the ability to reflect sufficient light to create a brilliant sparkle effect.

In contrast to traditional processing techniques and facet configurations used to fashion precious gemstones, significant material can be removed to create SiC gemstones. Rough SiC crystals can often be grown to sizes or weights much larger than the size or weight of the finished gemstone. Removing significant portions of SiC material doesn't necessarily affect the gemstone's value as larger finished stones can be fashioned from larger rough crystals. SiC gemstone facets can therefore be configured to reflect maximum light without undue concern about the amount of material removed to create the facets.

The facet configurations of the present invention include facets formed by the removal of significant gemstone material, in stark contrast to traditional gemstone facet configurations that aim to preserve gemstone weight. Further, the disclosed facet configurations are specifically designed for the properties of various forms of SiC-based gemstones. SiC gemstones formed with these facet configurations produce a more brilliant sparkle than similar stones formed using traditional facet configurations. As such, the currently disclosed configurations represent a significant departure from traditional gemstone facet configurations, and have been configured to reflect high levels of light for SiC-based gemstones. The facet configurations disclosed herein could also find use with other synthetic gemstones formed from materials with properties similar to SiC.

### SUMMARY OF THE INVENTION

A first aspect of the present invention includes a gemstone having a crown portion that can include a table facet, a plurality of trapezoidal facets, a plurality of irregular-hexagonal facets, a plurality of irregular-pentagonal facets, and a plurality of triangular crown-facets. The gemstone can also include a pavilion portion having a plurality of first kite facets, a plurality of irregular-quadrilateral facets, a plurality of second kite facets, and a plurality of triangular pavilion-facets.

A second aspect of the present invention includes a gemstone having a crown portion that can include a table facet, a plurality of triangular upper-crown facets, a plurality of four-sided polygonal facets, a plurality of triangular middle-crown facets, and a plurality of triangular lower-crown facets. The gemstone can also include a pavilion portion having a plurality of kite facets, a plurality of irregular-quadrilateral facets, a plurality of five-sided polygonal facets, a plurality of triangular middle-pavilion facets, and a plurality of triangular upper-pavilion facets.

A third aspect of the present invention includes a method of forming a gemstone. The method includes growing a single crystal of silicon carbide, forming a crown portion having a table facet and a plurality of triangular crown-facets, and forming a pavilion portion having a plurality of kite facets, a plurality of irregular-quadrilateral facets, and a plurality of triangular pavilion-facets.

A fourth aspect of the present invention includes a piece of jewelry having a setting configured to support a gemstone, wherein the gemstone can be at least partially formed from silicon carbide. The gemstone can include a crown portion having a table facet and a plurality of triangular crown-facets, and a pavilion portion having a plurality of kite facets, a plurality of irregular-quadrilateral facets, and a plurality of triangular pavilion-facets.

### BRIEF DESCRIPTION OF THE DRAWINGS

The accompanying drawings, which are incorporated in and constitute a part of this specification, illustrate several embodiments of the invention and together with the description, serve to explain the principles of the invention. In the drawings:

FIG. 1A is a side view of a standard round brilliant gemstone.

FIG. 1B is a top view of a standard round brilliant gemstone.

FIG. 1C is a bottom view of a standard round brilliant gemstone.

FIG. 2A is a side view of a gemstone, according to a first exemplary embodiment of the present invention.

FIG. 2B is a top view of a gemstone, according to a first exemplary embodiment of the present invention.

FIG. 2C is a bottom view of a gemstone, according to a first exemplary embodiment of the present invention.

FIG. 3A is a side view of a gemstone, according to a second exemplary embodiment of the present invention.

FIG. 3B is a top view of a gemstone, according to a second exemplary embodiment of the present invention.

FIG. 3C is a bottom view of a gemstone, according to a second exemplary embodiment of the present invention.

### DETAILED DESCRIPTION

Reference will now be made in detail to the present exemplary embodiments of the invention, examples of which are illustrated in the accompanying drawings. Whenever possible, the same reference numbers will be used throughout the drawings to refer to the same or like parts.

### Facet Configurations

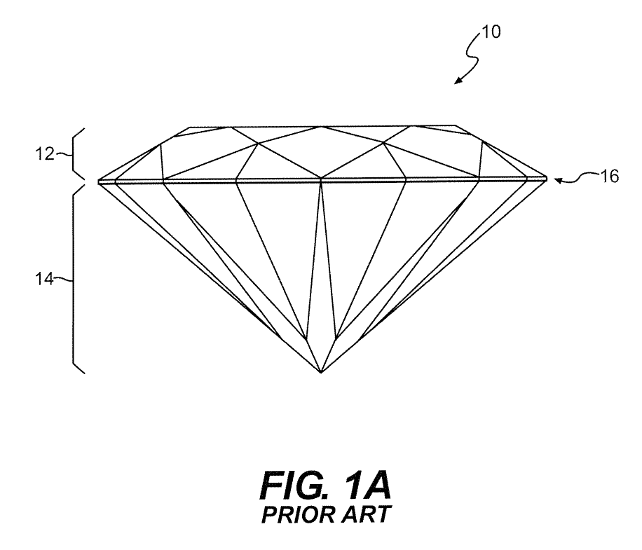

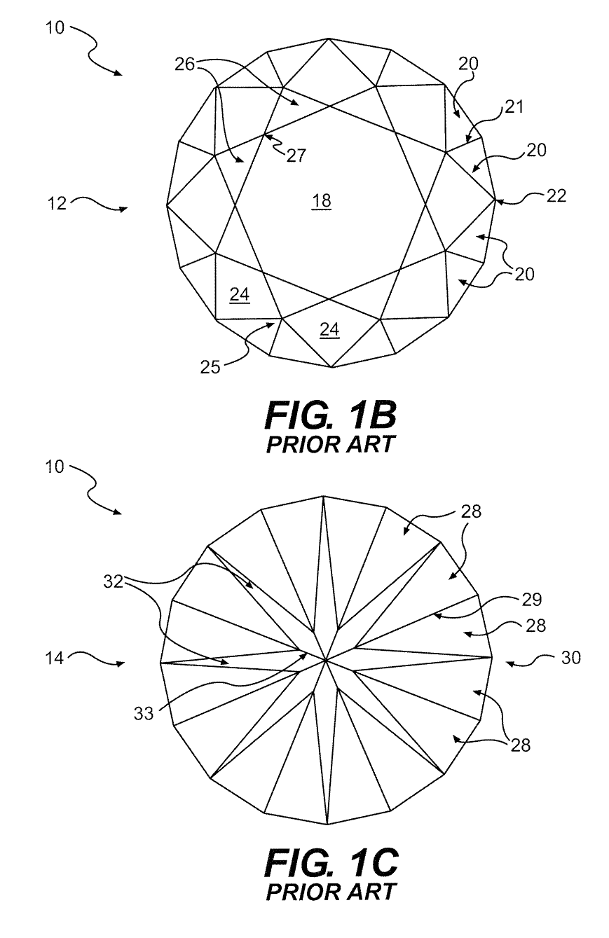

FIG. 1A is a side view of a standard round brilliant gemstone 10. In some embodiments, at least a portion of gemstone 10 can have a refractive index of about 2.65, or can be at least partially formed from silicon carbide (SiC). Gemstone 10 can be any suitable dimension, size, or weight. As shown in FIGS. 1A, 1B, and 1C, and explained in detail below, gemstone 10 can have an 8-fold mirror-image symmetry. In other embodiments, gemstone 10 can include a 4, 6, 10 or 12-fold symmetry. In yet other embodiments, gemstone 10 can include other levels or symmetry, or can be asymmetric.

Gemstone 10 can generally include two portions, a crown 12 and a pavilion 14. Crown 12 can include the generally top or upper portion of gemstone 10, while pavilion 14 can include the generally bottom or lower portion of gemstone 10. In some embodiments, a girdle 16 can be located between crown 12 and pavilion 14. Both crown 12 and pavilion 14 can also include a plurality of flat facet surfaces, as described in detail below.

Facets described herein can be substantially or generally flat. Facets can also be formed into various geometric shapes. These shapes can be described using precise terms although the actual form of the shape may vary. For example, a triangular facet can include a substantially or generally triangular shape including three sides. The triangular facet may include straight or arcuate sides. Further, the combined summation of angles of the three vertices could be about 180°, such as, for example, 160° or 200°. Similar variation could occur with other parameters of the triangular facet, or any other facet geometry described herein. These and other geometries, angles, configurations, or arrangements of facets described herein are general descriptions and not precise mathematical definitions. For example, angles described herein can include a range of variation, such as, for example, ±¼°, ±½°, ±1°, or ±2°, depending upon material properties, such as the refractive index. Also, the term radially can include arrangements that are generally or approximately radial in distribution.

FIG. 1B is a top view of standard round brilliant gemstone 10, showing crown 12. As shown in FIG. 1B, crown 12 includes a table facet 18 and various facets arranged in an 8-fold symmetrical pattern between table facet 18 and the perimeter of crown 12. Crown 12 can also include three sets of generally symmetrical facets. A set, or plurality, of first crown-facets 20 can have at least one boundary in common with the perimeter of crown 12. Although only four facets of the plurality of first crown-facets 20 are indicated, the plurality of first crown-facets 20 can be arranged to extend generally around the circumference of crown 12, and can include a total of sixteen facets. As shown, each first crown-facet 20 can be in contact with an adjacent first crown-facet 20 such that two adjacent first crown-facets 20 share a common boundary. This common boundary can include an edge boundary 21 or a point boundary 22. A boundary can include a point or edge, wherein the edge can be arcuate or linear. Boundaries of facets may or may not be symmetric.

Crown 12 can also include a plurality of second crown-facets 24. Although only two facets of the plurality of second crown-facets 24 are indicated, plurality of second crown-facets 24 can generally extend around table facet 18, and can include a total of eight facets. As shown, each second crown-facet 24 can share a common boundary with an adjacent second crown-facet 24, as indicated by a point boundary 25.

Further, crown 12 can include a plurality of third crown-facets 26. Although only two facets of plurality of third crown-facets 26 are indicated, plurality of third crown-facets 26 can generally extend around the perimeter of table facet 18, and can include a total of eight facets. As shown, each third crown-facet 26 shares a common boundary with an adjacent third crown-facet 26, as indicated by a point boundary 27.

In some embodiments, at least one plurality of first crown-facets 20 can be formed at an angle of about 34° with the horizontal plane of gemstone 10. Also, at least one second and third crown-facets 24, 26 can be formed at angles of about 28° and about 16°, respectively, with the horizontal plane of gemstone 10.

FIG. 1C is a bottom view of standard round brilliant gemstone 10, showing pavilion 14. As shown in FIG. 1C, pavilion 14 includes various facets arranged in an 8-fold symmetrical pattern. Pavilion 14 can also include two sets of generally symmetric facets. A plurality of first pavilion-facets 28 can have at least one boundary in common with the perimeter of pavilion 14. Although only five facets of the plurality of first pavilion-facets 28 are indicated, plurality of first pavilion-facets 28 can be arranged to extend generally around the circumference of pavilion 14, and can include a total of sixteen facets. As shown, each plurality of first pavilion-facets 28 can be in contact with an adjacent first pavilion-facet 28 such that two adjacent first pavilion-facets 28 share a common boundary. This common boundary can include an edge boundary 29 or a point boundary 30.

Pavilion 14 can also include a plurality of second pavilion-facets 32. Although only two facets of plurality of second pavilion-facets 32 are indicated, plurality of second pavilion-facets 32 can be arranged to extend generally around pavilion 14, radiating out from the center of pavilion 14, and can include a total of eight facets. As shown, each second pavilion-facet 32 can share a common boundary with an adjacent second pavilion-facet 32, as indicated by an edge boundary 33.

In some embodiments, for pavilion 14, at least one first pavilion-facet 28 can be formed at an angle of about 41° with the horizontal plane of gemstone 10, and at least one second facet 32 can be formed at an angle of about 40° with the horizontal plane of gemstone 10.

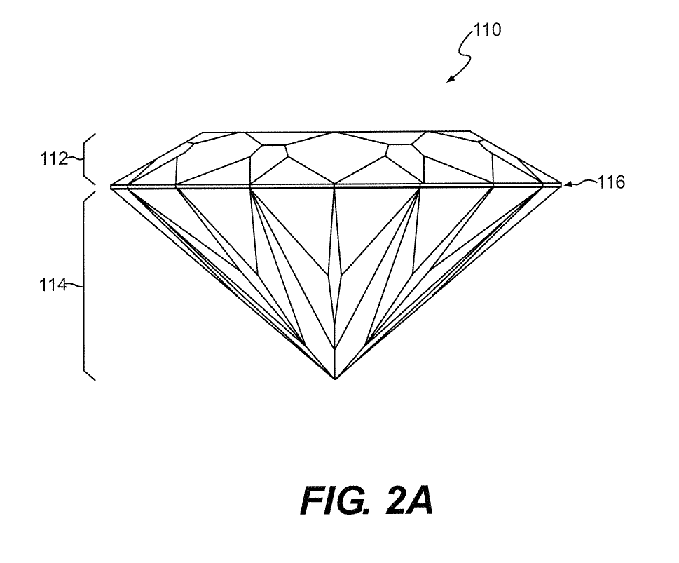

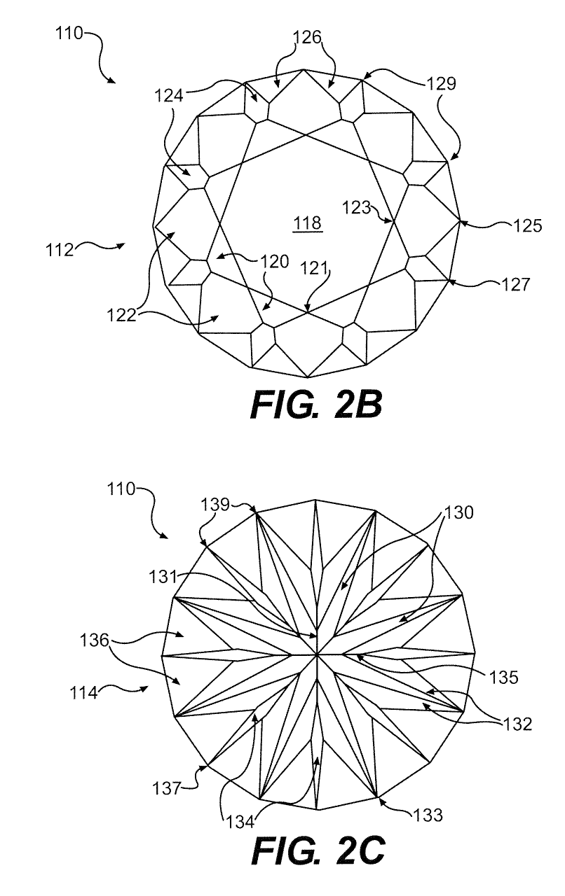

FIG. 2A is a side view of a gemstone 110, according to a first exemplary embodiment of the present invention. In some embodiments, at least a portion of gemstone 110 can have a refractive index of about 2.65, or can be at least partially formed from SiC. Gemstone 110 can be any suitable dimension, size, or weight. As shown in FIGS. 2A, 2B, and 2C, and explained in detail below, gemstone 110 can have an 8-fold mirror-image symmetry. In other embodiments, gemstone 110 can include a 4, 6, 10 or 12-fold symmetry. In yet other embodiments, gemstone 110 can include other levels or symmetry, or can be asymmetric.

Gemstone 110 can generally include two portions, a crown 112 and a pavilion 114. Crown 112 can include the generally top or upper portion of gemstone 110, while pavilion 114 can include the generally bottom or lower portion of gemstone 110. In some embodiments, a girdle 116 can be located between crown 112 and pavilion 114. Girdle 116 can include a curved facet, a flat facet, or any number of curved or flat facets. Both crown 112 and pavilion 114 can also include a plurality of facet surfaces, as described in detail below.

FIG. 2B is a top view of gemstone 110, showing crown 112, according to a first exemplary embodiment of the present invention. As shown in FIG. 2B, crown 112 can include a table facet 118 and various facets arranged in an 8-fold symmetrical pattern between table facet 118 and the perimeter of crown 112. Crown 112 can also include a number of sets of generally symmetric facets. In some embodiments, crown 112 can include a plurality of trapezoidal facets 120, a plurality of irregular-hexagonal facets 122, a plurality of irregular-pentagonal facets 124, and a plurality of triangular crown-facets 126.

In some embodiments, plurality of trapezoidal facets 120 can have a boundary in common with a boundary of table facet 118. Although only two facets of plurality of trapezoidal facets 120 are indicated, plurality of trapezoidal facets 120 can be arranged to extend generally around table facet 118, and can include a total of eight facets. As shown, each trapezoidal facet 120 can be in contact with an adjacent trapezoidal facet 120 such that two adjacent trapezoidal facets 120 can share a common boundary 121. Further, at least one of plurality of trapezoidal facets 120 can be formed at an angle of about 16° with the horizontal plane of gemstone 110.

Plurality of irregular-hexagonal facets 122 can have a first boundary 123 in common with a boundary of table facet 118 and a second boundary 125 in common with the perimeter of crown 112. Although only two facets of irregular-hexagonal facets 122 are indicated, irregular-hexagonal facets 122 can be generally radially arranged around table facet 118, and can include a total of eight facets. Further, at least one of plurality of irregular-hexagonal facets 122 can be formed at an angle of about 28° with the horizontal plane of gemstone 110.

Crown 112 can also include plurality of irregular-pentagonal facets 124, wherein plurality of irregular-pentagonal facets 124 can have a boundary 127 in common with the perimeter of crown 112. Although only two facets of irregular-pentagonal facets 124 are indicated, irregular-pentagonal facets 124 can be generally radially arranged between table facet 118 and the perimeter of crown 112, and can include a total of eight facets. In addition, at least one of plurality of irregular-pentagonal facets 124 can be formed at an angle of about 31° with the horizontal plane of gemstone 110.

Also, crown 112 can include plurality of triangular crown-facets 126. Although only two facets of triangular crown-facets 126 are indicated, triangular crown-facets 126 can generally extend around the perimeter of crown 112, and can include a total of sixteen facets. As shown, each triangular crown-facet 126 can share at least one common boundary with an adjacent triangular crown-facet 126, as indicated by a boundary 129. At least one of plurality of triangular crown-facet 126 can also be formed at an angle of about 34° with the horizontal plane of gemstone 110.

FIG. 2C is a bottom view of gemstone 110, showing pavilion 114, according to a first exemplary embodiment of the present invention. As shown in FIG. 2C, pavilion 114 can include various facets arranged in an 8-fold symmetrical pattern. Pavilion 114 can also include four sets of generally symmetric facets. In some embodiments, pavilion 114 can include a plurality of first kite facets 130, a plurality of irregular-quadrilateral facets 132, a plurality of second kite facets 134, and a plurality of triangular pavilion-facets 136.

In some embodiments, at least two of plurality of first kite facets 130 can have a common boundary 131. Also, plurality of first kite facets 130 can be radially arranged around the center of pavilion 114. Although only two facets of plurality of first kite facets 130 are indicated, plurality of first kite facets 130 can include a total of eight facets. Further, at least one of plurality of first kite facets 130 can be formed at an angle of about 39.5° with the horizontal plane of gemstone 110.

Plurality of irregular-quadrilateral facets 132 can have a boundary 133 in common with the perimeter of pavilion 114. Also, at least two of plurality of irregular-quadrilateral facets 132 can have a boundary 135 in common. Although only two facets of irregular-quadrilateral facets 132 are indicated, irregular-quadrilateral facets 132 can be generally radially arranged around the center of pavilion 114, and can include a total of sixteen facets. Further, at least one of plurality of irregular-quadrilateral facets 132 can be formed at an angle of about 40° with the horizontal plane of gemstone 110.

Pavilion 114 can also include plurality of second kite facets 134, wherein plurality of second kite facets 134 can have a boundary 137 in common with the perimeter of pavilion 114. Although only two facets of plurality of second kite facets 134 are indicated, plurality of second kite facets 134 can be radially arranged between the center and perimeter of pavilion 114, and can include a total of eight facets. In addition, at least one of plurality of second kite facets 134 can be formed at an angle of about 40° with the horizontal plane of gemstone 110.

Also, pavilion 114 can include plurality of triangular pavilion-facets 136. Although only two facets of triangular pavilion-facets 136 are indicated, plurality of triangular pavilion-facets 136 can generally extend around the perimeter of pavilion 114, and can include a total of sixteen facets. As shown, each triangular pavilion-facet 136 can share at least one common boundary with an adjacent triangular pavilion-facets 136, as indicated by a boundary 139. At least one of plurality of triangular pavilion-facets 136 can also be formed at an angle of about 41° with the horizontal plane of gemstone 110.

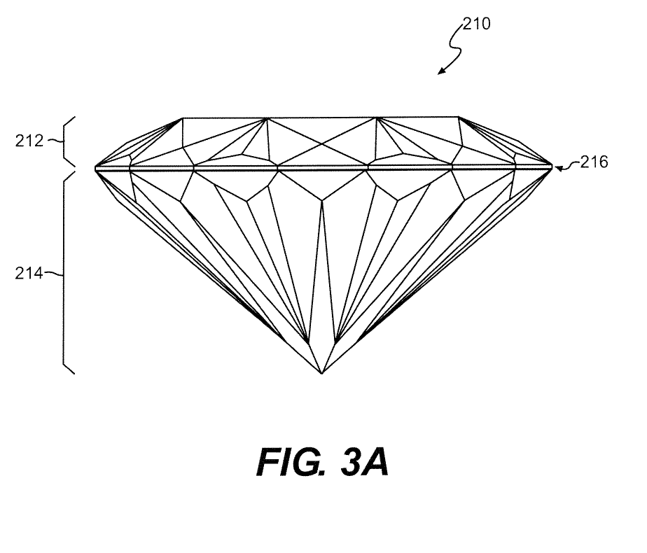

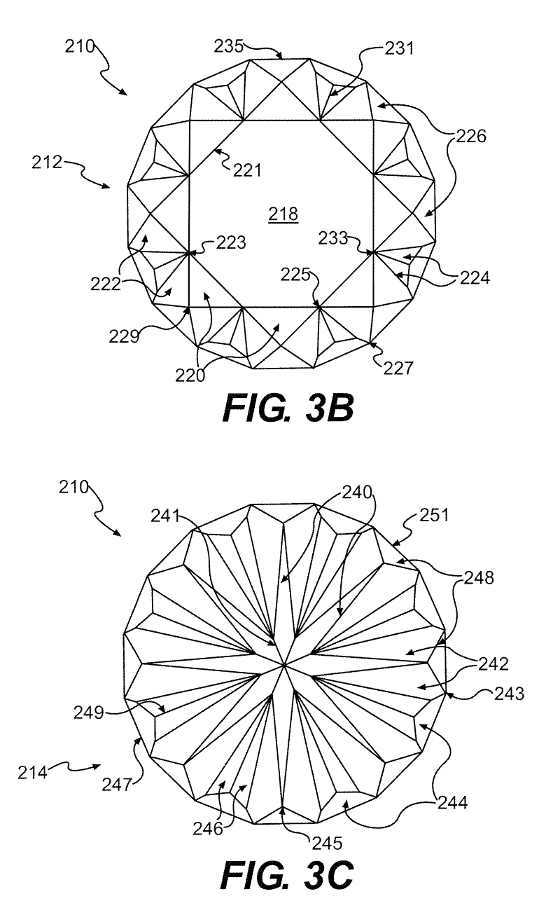

FIG. 3A is a side view of a gemstone 210, according to a second exemplary embodiment of the present invention. In some embodiments, at least a portion of gemstone 210 can have a refractive index of about 2.65, or can be at least partially formed from SiC. Gemstone 210 can be any suitable dimension, size, or weight. As shown in FIGS. 3A, 3B, and 3C, and explained in detail below, gemstone 210 can have an 8-fold mirror-image symmetry. In other embodiments, gemstone 210 can have a 4, 6, 10 or 12-fold symmetry. In yet other embodiments, gemstone 210 can include other levels or symmetry, or can be asymmetric.

Gemstone 210 can generally include two portions, a crown 212 and a pavilion 214. Crown 212 can include the generally top or upper portion of gemstone 210, while pavilion 214 can include the generally bottom or lower portion of gemstone 210. In some embodiments, a girdle 216 can be located between crown 212 and pavilion 214. Girdle 216 can include a curved facet, a flat facet, or any number of curved or flat facets. Both crown 212 and pavilion 214 can also include a plurality of facet surfaces, as described in detail below.

FIG. 3B is a top view of gemstone 210, showing crown 212, according to a second exemplary embodiment of the present invention. As shown in FIG. 3B, crown 212 can include a table facet 218 and various facets arranged in an 8-fold symmetrical pattern between table facet 218 and the perimeter of crown 212. Crown 212 can also include a number of sets of generally symmetric facets. In some embodiments, crown 212 can include a plurality of triangular upper-crown facets 220, a plurality of four-sided polygonal facets 222, a plurality of triangular middle-crown facets 224, and a plurality of triangular lower-crown facets 226.

In some embodiments, at least one of plurality of triangular upper-crown facets 220 can have a boundary 221 in common table facet 218. Although only two facets of plurality of triangular upper-crown facets 220 are indicated, plurality of triangular upper-crown facets 220 can be arranged to extend generally around table facet 218, and can include a total of eight facets. As shown, each of triangular upper-crown facets 220 can be in contact with an adjacent triangular upper-crown facet 220 such that two adjacent triangular upper-crown facets 220 can share a common boundary 223. Further, at least one of plurality of triangular upper-crown facets 220 can be formed at an angle of about 23° with the horizontal plane of gemstone 210.

Plurality of four-sided polygonal facets 222 can have a first boundary 225 in common with table facet 218 and a second boundary 227 in common with the perimeter of crown 212. Although only two facets of four-sided polygonal facets 222 are indicated, four-sided polygonal facets 222 can be generally radially arranged between table facet 218 and the perimeter of crown 212, and can include a total of sixteen facets. Two adjacent four-sided polygonal facets 222 can also share a common boundary 229. Further, at least one of plurality of four-sided polygonal facets 222 can be formed at an angle of about 28° with the horizontal plane of gemstone 210.

Crown 212 can also include plurality of triangular middle-crown facets 224, wherein two adjacent triangular middle-crown facets 224 can have a boundary 231 in common. At least one triangular middle-crown facets 224 can also have a boundary 233 with table facet 218. Although only two facets of triangular middle-crown facets 224 are indicated, triangular middle-crown facets 224 can be generally radially arranged between table facet 218 and the perimeter of crown 212, and can include a total of sixteen facets. In addition, at least one of plurality of triangular middle-crown facets 224 can be formed at an angle of about 29° with the horizontal plane of gemstone 210.

Also, crown 212 can include plurality of triangular lower-crown facets 226. Although only two facets of triangular lower-crown facets 226 are indicated, triangular lower-crown facets 226 can generally extend around the perimeter of crown 212, and can include a total of eight facets. As shown, at least one triangular lower-crown facet 226 can share a common boundary with the perimeter of crown 212, as indicated by a boundary 235. At least one of plurality of triangular lower-crown facets 226 can also be formed at an angle of about 34° with the horizontal plane of gemstone 210.

FIG. 3C is a bottom view of gemstone 210, showing pavilion 214, according to a second exemplary embodiment of the present invention. As shown in FIG. 3C, pavilion 214 can include various facets arranged in an 8-fold symmetrical pattern. Pavilion 214 can also include five sets of generally symmetrical facets. In some embodiments, pavilion 214 can include a plurality of kite facets 240, a plurality of irregular-quadrilateral facets 242, a plurality of five-sided polygonal facets 244, a plurality of triangular middle-pavilion facets 246, and a plurality of triangular upper-pavilion facets 248.

In some embodiments, at least two of plurality of kite facets 240 can have a common boundary 241. Also, plurality of kite facets 240 can be generally radially arranged around the center of pavilion 214. Although only two facets of plurality of kite facets 240 are indicated, plurality of kite facets 240 can include a total of eight facets. Further, at least one of plurality of kite facets 240 can be formed at an angle of about 40° with the horizontal plane of gemstone 210.

Plurality of irregular-quadrilateral facets 242 can have a boundary 243 in common with the perimeter of pavilion 214. Also, at least two of plurality of irregular-quadrilateral facets 242 can have a boundary 245 in common. Although only two facets of irregular-quadrilateral facets 242 are indicated, irregular-quadrilateral facets 242 can be generally radially arranged between the center and the perimeter of pavilion 114, and can include a total of sixteen facets. Further, at least one of plurality of irregular-quadrilateral facets 242 can be formed at an angle of about 41° with the horizontal plane of gemstone 210.

Pavilion 214 can also include plurality of five-sided polygonal facets 244, wherein plurality of five-sided polygonal facets 244 can have a boundary 247 in common with the perimeter of pavilion 214. Although only two facets of plurality of five-sided polygonal facets 244 are indicated, plurality of five-sided polygonal facets 244 can be generally radially arranged around the perimeter of pavilion 214, and can include a total of eight facets. In addition, at least one of plurality of five-sided polygonal facets 244 can be formed at an angle of about 47° with the horizontal plane of gemstone 210.

Also, pavilion 214 can include plurality of triangular middle-pavilion facets 246. Although only two facets of triangular middle-pavilion facets 246 are indicated, triangular middle-pavilion facets 246 can be generally radially arranged between the center and perimeter of pavilion 214, and can include a total of sixteen facets. As shown, each triangular middle-pavilion facets 246 can share at least one common boundary with an adjacent triangular middle-pavilion facets 246, as indicated by a boundary 249. At least one of plurality of triangular middle-pavilion facets 246 can also be formed at an angle of about 41° with the horizontal plane of gemstone 210.

Pavilion 114 can further include plurality of triangular upper-pavilion facets 248. Although only two facets of triangular upper-pavilion facets 248 are indicated, plurality of triangular upper-pavilion facets 248 can be generally arranged around the perimeter of pavilion 214, and can include a total of eight facets. As shown, each triangular upper-pavilion facets 248 can have a common boundary with the perimeter of pavilion 214, as indicated by a boundary 251. At least one of plurality of triangular upper-pavilion facets 248 can also be formed at an angle of about 49° with the horizontal plane of gemstone 210.

### Manufacturing Methods

Gemstones 10, 110, 210 can be produced from SiC using any suitable method. SiC-based gemstones of various polytypes can also be used. For example, SiC can be formed with 8.50-9.25 Mohs hardness, or a refractive index of 2.50-2.71, depending on the polytype. In some embodiments, gemstones 10, 110, 210 may include material that includes silicon carbide and non-silicon carbide material, such as, for example, diamond, as described in more detail in U.S. Pat. No. 5,882,786, the teachings of which is hereby incorporated by reference in its entirety.

For example, a suitable crystal can be formed by a deposition process or other technique used to grow large single crystals of SiC. One method includes a sublimation technique, wherein crystal growth can be initiated by introducing a polished mono-crystalline seed crystal of SiC and desired polytype into a furnace containing sources of silicon and carbon, such as, for example, gas or powder. The source material can be heated to form a vapor for deposition on the seed crystal. Reproducible crystal growth can be achieved by maintaining a constant vapor flux and controlling the thermal conditions of the source material and the seed crystal.

Various crystalline forms of SiC can be used as seed material. For example, the polytypes 6H and 4H can be used as SiC seed structures to initiate crystal growth. Also, various dopants can be used to at least partially color SiC crystals. Nitrogen and aluminum can be used to impart different colors, depending on the type of seed lattice. Other n-type and p-type dopants could also be used.

Chemical compounds with properties similar to SiC could also be used to form the gemstone facet configurations described herein. For example, other chemical compounds that have a similar refractive index could be used to grow synthetic crystals that could be formed into the facet configurations described above. General variations of the facet parameters will be influenced by different properties. For example, materials having a refractive index within the general range of SiC, but higher than diamond, could be formed with the facet configurations described herein.

Following growth and formation of a suitably sized rough crystal, the rough crystal must be fashioned to form a final gemstone configuration. These steps can include faceting, polishing, grinding, and other similar techniques.

Once a gemstone is processed, it can be mounted in jewelry. Jewelry can include a wide range of objects, worn or displayed as desired. Most jewelry suitable for use with a gemstone can include a setting, or other similar device configured to support the gemstone. The setting can be made of any appropriate material, such as, for example, gold, silver and titanium. Generally, the setting should be designed to provide a suitable structure to permit light to enter the gemstone such that the light can be reflected to create a brilliant sparkle effect.

It will be apparent to those skilled in the art that various modifications and variations can be made in the disclosed materials and methods without departing from the scope of the invention. Other embodiments of the disclosed materials and methods will be apparent to those skilled in the art from consideration of the specification and practice of the embodiments disclosed herein. It is intended that the specification and examples be considered as exemplary only, with a true scope of the invention being indicated by the following claims and their equivalents.

What is claimed is:

1. A gemstone comprising:
a crown portion having a table facet, a plurality of trapezoidal facets, a plurality of irregular-hexagonal facets, a plurality of irregular-pentagonal facets, and a plurality of triangular crown-facets; and
a pavilion portion having a plurality of first kite facets, a plurality of irregular-quadrilateral facets, a plurality of second kite facets, and a plurality of triangular pavilion-facets.

2. The gemstone of claim 1, wherein the gemstone comprises silicon carbide.

3. The gemstone of claim 1, wherein the gemstone has a refractive index in the range of about 2.50 to about 2.71.

4. The gemstone of claim 1, further including a girdle positioned between the crown and the pavilion.

5. The gemstone of claim 1, wherein the gemstone includes at least one of 4, 6, 8, 10 and 12-fold symmetry.

6. The gemstone of claim 1, wherein at least one of the plurality of trapezoidal facets has a boundary in common with a boundary of the table facet.

7. The gemstone of claim 1, wherein at least one of the plurality of irregular-hexagonal facets has a first boundary in common with a boundary of the table facet and a second boundary in common with the perimeter of the crown.

8. The gemstone of claim 1, wherein at least one of the plurality of irregular-pentagonal facets has a boundary in common with the perimeter of the crown.

9. The gemstone of claim 1, wherein at least two of the plurality of first kite facets have a common boundary.

10. The gemstone of claim 1, wherein at least one of the plurality of irregular-quadrilateral facets has a boundary in common with the perimeter of the pavilion and at least two of the plurality of irregular-quadrilateral facets have a common boundary.

11. The gemstone of claim 1, wherein at least one of the plurality of irregular-pentagonal facets is formed at an angle of about 31° with the horizontal plane of the gemstone.

12. The gemstone of claim 1, wherein at least one of the plurality of irregular-quadrilateral facets is formed at an angle of about 40° with the horizontal plane of the gemstone.

13. The gemstone of claim 1, wherein at least one of the plurality of first kite facets is formed at an angle of about 39.5° with the horizontal plane of the gemstone.

14. A gemstone comprising:
a crown portion having a table facet, a plurality of triangular upper-crown facets, a plurality of four-sided polygonal facets, a plurality of triangular middle-crown facets, and a plurality of triangular lower-crown facets; and
a pavilion portion having a plurality of kite facets, a plurality of irregular-quadrilateral facets, a plurality of five-sided polygonal facets, a plurality of triangular middle-pavilion facets, and a plurality of triangular upper-pavilion facets.

15. The gemstone of claim 14, wherein the gemstone comprises silicon carbide.

16. The gemstone of claim 14, wherein the gemstone has a refractive index in the range of about 2.50 to about 2.71.

17. The gemstone of claim 14, further including a girdle positioned between the crown and the pavilion.

18. The gemstone of claim 14, wherein the gemstone includes at least one of 4, 6, 8, 10 and 12-fold symmetry.

19. The gemstone of claim 14, wherein at least one of the plurality of triangular upper-crown facets has a boundary in common with the table facet.

20. The gemstone of claim 14, wherein at least two of the plurality of triangular middle-crown facets have a common boundary.

21. The gemstone of claim 14, wherein at least two of the plurality of triangular middle-pavilion facets have a common boundary.

22. The gemstone of claim 14, wherein at least one of the plurality of triangular upper-pavilion facets has a boundary in common with the perimeter of the pavilion.

23. The gemstone of claim 14, wherein at least one of the plurality of five-sided polygonal facets has a boundary in common with the perimeter of the pavilion.

24. The gemstone of claim 14, wherein at least one of the plurality of triangular upper-crown facets is formed at an angle of about 23° with the horizontal plane of the gemstone.

25. The gemstone of claim 14, wherein at least one of the plurality of triangular middle-crown facets is formed at an angle of about 29° with the horizontal plane of the gemstone.

26. The gemstone of claim 14, wherein at least one of the plurality of triangular upper-pavilion facets is formed at an angle of about 49° with the horizontal plane of the gemstone.

27. The gemstone of claim 14, wherein at least one of the plurality of triangular middle-pavilion facets is formed at an angle of about 41° with the horizontal plane of the gemstone.

28. The gemstone of claim 14, wherein at least one of the plurality of five-sided polygonal facets is formed at an angle of about 47° with the horizontal plane of the gemstone.

29. A method of forming a gemstone, comprising:
growing a single crystal of silicon carbide;
forming a crown portion having a table facet and a plurality of triangular crown-facets; and
forming a pavilion portion having a plurality of kite facets, a plurality of irregular-quadrilateral facets, and a plurality of triangular pavilion-facets.

30. The method of claim 29, wherein growing the single crystal includes using a sublimation process.

31. The method of claim 29, further including selectively doping the single crystal to at least partially color the crystal.

32. The method of claim 29, wherein the single crystal has a crystalline form selected from the group consisting of a 6H structure and a 4H structure.

33. The method of claim 29, wherein the crown portion further includes a plurality of trapezoidal facets, a plurality of irregular-hexagonal facets, and a plurality of irregular-pentagonal facets.

34. The method of claim 33, wherein at least one of the plurality of irregular-pentagonal facets is formed at an angle of about 31° with the horizontal plane of the gemstone.

35. The method of claim 29, wherein the pavilion portion further includes a plurality of second kite facets.

36. The method of claim 29, wherein at least one of the plurality of irregular-quadrilateral facets is formed at an angle of about 40° with the horizontal plane of the gemstone.

37. The method of claim 29, wherein at least one of the plurality of kite facets is formed at an angle of about 39.5° with the horizontal plane of the gemstone.

38. The method of claim 29, wherein the crown portion further includes a plurality of four-sided polygonal facets.

39. The method of claim 29, wherein at least one of the plurality of triangular crown-facets is formed at an angle with the horizontal plane of the gemstone selected from the group consisting of about 23° and about 29°.

40. The method of claim 29, wherein the pavilion portion further includes a plurality of five-sided polygonal facets.

41. The method of claim 40, wherein at least one of the plurality of five-sided polygonal facets is formed at an angle of about 47° with the horizontal plane of the gemstone.

42. The method of claim 29, wherein at least one of the plurality of triangular pavilion-facets is formed at an angle with the horizontal plane of the gemstone selected from the group consisting of about 41° and about 49°.

43. An item of jewelry comprising:
a setting configured to support a gemstone, wherein the gemstone comprises silicon carbide and includes:
a crown portion having a table facet and a plurality of triangular crown-facets; and
a pavilion portion having a plurality of kite facets, a plurality of irregular-quadrilateral facets, and a plurality of triangular pavilion-facets.

44. The item of jewelry of claim 43, wherein the setting includes a precious metal selected from the group consisting of gold, silver, and titanium.

45. The item of jewelry of claim 43, wherein the crown portion further includes a plurality of trapezoidal facets, a plurality of irregular-hexagonal facets, and a plurality of irregular-pentagonal facets.

46. The item of jewelry of claim 43, wherein the pavilion portion further includes a plurality of second kite facets.

47. The item of jewelry of claim 43, wherein the crown portion further includes a plurality of four-sided polygonal facets.

48. The item of jewelry of claim 43, wherein the pavilion portion further includes a plurality five-sided polygonal facets.
